(19) United States
(12) Patent Application Publication
(10) Pub. No.: US 2019/0085433 A1
(43) Pub. Date: Mar. 21, 2019

(54) HIGH THERMAL CONDUCTIVE MAGNESIUM ALLOY AND HEAT SINK USING THE SAME

(71) Applicant: LG ELECTRONICS INC., Seoul (KR)

(72) Inventors: Myeon Chang Sung, Seoul (KR); Joongnyon Kim, Seoul (KR); Sunghyun Park, Seoul (KR); Vyacheslav E. Bazhenov, Moskva (RU); Andrey V. Koltygin, Moskva (RU)

(73) Assignee: LG ELECTRONICS INC.

(21) Appl. No.: 15/903,433

(22) Filed: Feb. 23, 2018

Related U.S. Application Data
(60) Provisional application No. 62/558,876, filed on Sep. 15, 2017.

(30) Foreign Application Priority Data
Sep. 29, 2017 (KR) 10-2017-0128223

(51) Int. Cl. C22C 23/04; H01L 23/373

(52) U.S. Cl. CPC C22C 23/04; H01L 23/3736

(57) ABSTRACT

A magnesium (Mg) alloy having lightweight and excellent thermal conductivity, and a heat sink including the magnesium (Mg) alloy are provided. The magnesium (Mg) alloy may include one or more alloy additive elements selected from the group consisting of silicon (Si), calcium (Ca), tin (Sn), yttrium (Y), iron (Fe), nickel (Ni), copper (Cu), cerium (Ce), cesium (Cs), antimony (Sb), cobalt (Co), thorium (Th), and silver (Ag). Some of the alloy additive elements may be dissolved in the magnesium alloy to form a solid solution. The alloy additive elements that form the solid solution at room temperature may account for 2 wt % or less, based on the total weight (100 wt %) of the magnesium alloy, and the alloy additive elements that do not form the solid solution may be in crystalline phases.

### CROSS-REFERENCE TO RELATED APPLICATIONS

This application claims priority under 35 U.S.C. § 119 to U.S. Provisional Application No. 62/558,876, filed on Sep. 15, 2017; and Korean Application No. 10-2017-0128223, filed on Sep. 29, 2017, whose entire disclosures are incorporated herein by reference.

### BACKGROUND

### 1. Field

A high thermally conductive magnesium alloy and a heat sink using a high thermally conductive magnesium alloy are disclosed herein.

### 2. Background

As electronic products, such as, for example, automobiles, household appliances, lighting, and other electronic devices, are being developed to have high performance, heat generation is becoming more of a problem in such products. Accordingly, a heat sink that dissipates heat may be used in electronic products generating heat. Aluminum (Al) has been widely used as a material for heat sinks, but research on alternative materials have been pursued due to global trends in environmental regulation and a need for lighter materials in fields such as, for example, automobiles and electronic devices. Among heat-dissipating materials used for heat sinks, magnesium (Mg) and heat-dissipating plastics, for example, are lighter than aluminum. Although magnesium and heat-dissipating plastics are lightweight materials, their low thermal conductivity may make it difficult to replace aluminum for heat sinks.

An amount of heat dissipation of heat sinks may be measured, as follows:

Q=(kA/L)·ΔT
(Q=amount of heat dissipation, k=thermal conductivity, A=heat-dissipating area, L=length, T=temperature)

The amount of heat dissipation, which indicates heat dissipation performance, is directly related to the thermal conductivity of heat sink materials and area of the heat sink. In order to achieve a maximum heat dissipation effect, it may be necessary not only to use a material having high thermal conductivity but also to make it possible to manufacture a shape capable of maximizing an area of a heat sink. In order to obtain the maximum heat dissipation effect, it may be necessary to use extrusion materials or casting materials rather than wrought products because a heat sink with such a shape may be essential.

Magnesium materials as a next generation lightweight material have a density of about two thirds (⅔) of that of aluminum, but have a low thermal conductivity. AZ91 alloy, a typical, commercial magnesium casting material, has a thermal conductivity of 53 W/m·K, which is only half the thermal conductivity of ADC12, a commercial aluminum casting material, which has a thermal conductivity of 92 W/m·K. Therefore, a high thermal conductive magnesium alloy may replace an aluminum in a heat sink for use in electronic products, and may be more lightweight and castable.

### BRIEF DESCRIPTION OF THE DRAWINGS

The embodiments will be described in detail with reference to the following drawings in which like reference numerals refer to like elements, and wherein:

FIG. 1 is a perspective view of a cooling fin;

FIG. 2 is a graph of hot tear cracking depending on zinc content of a magnesium alloy according to an embodiment;

FIG. 3A and FIG. 3B are Electron Back Scattered Diffraction (EBSD) phase maps of a commercial magnesium alloy and the magnesium alloy according to an embodiment;

FIG. 4 is a Scanning Electron Microscope (SEM) image showing a silicon (Si) crystalline phase morphology of a high thermally conductive magnesium alloy according to an embodiment;

FIG. 5A to FIG. 5D are images showing microstructures of magnesium alloy samples according to an embodiment, observed with an electron microscopy Energy Dispersive Spectrometer (EDS) and EBSD; and

FIG. 6 is a graph showing thermal conductivity depending on magnesium content for example embodiments and comparative examples.

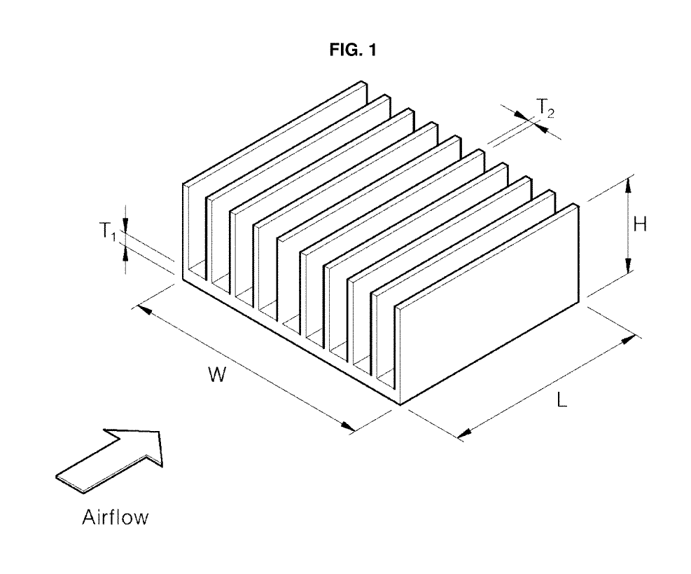

### DETAILED DESCRIPTION

With respect to thermal conductivity, the thermal conductivity of a pure metal is generally higher than the thermal conductivity of an alloy. For example, although the thermal conductivity of pure magnesium (Mg) is about 155 W/m·K, thermal conductivity may decrease if the magnesium is made into an alloy. This is because another element or other elements added for alloying may be a factor preventing movement of electrons, which transfer heat internally. Commercial magnesium alloys may include aluminum (Al) as a main additive element. Since aluminum has a melting point almost similar to a melting point of magnesium and is readily dissolved in or with magnesium to form a solid solution, it may be widely used as an additive. A magnesium alloy may include aluminum as a main additive element in an amount of about 2 wt % to 9 wt % to improve strength and casting properties.

Elements such as, for example, aluminum (Al), tin (Sn), manganese (Mn), lead (Pb), having high specific resistivities, may exhibit low electric conductivity. Since thermal conductivity is proportional to electric conductivity, elements such as aluminum (Al), tin (Sn), manganese (Mn), or lead (Pb) may be added to magnesium (Mg), decreasing thermal conductivity. Therefore, the thermal conductivity of a commercial magnesium alloy including aluminum as a main additive element may be reduced, compared to the thermal conductivity of pure magnesium metal. In the case of AZ91, a commercial magnesium alloy, about 9 wt % of aluminum is added, resulting in a large reduction of thermal conductivity to about 53 W/m·K, which is ⅓ of the thermal conductivity of pure magnesium metal. In the case of ADC12, a commercial aluminum alloy with a thermal conductivity of about 92 W/m·K, the thermal conductivity resulting from the addition of aluminum is reduced to about or a little more than ½ of the thermal conductivity of pure magnesium metal.

Embodiments disclosed herein may improve the low thermal conductivity of conventional, commercial alloys and provide a high thermally conductive magnesium alloy, without elements such as aluminum significantly reducing thermal conductivity, or, if aluminum is included, having aluminum content to 1 wt % or less.

A magnesium alloy according to embodiments disclosed herein may include one or more alloy additive elements selected from the group consisting of silicon (Si), calcium (Ca), tin (Sn), yttrium (Y), iron (Fe), nickel (Ni), copper (Cu), cerium (Ce), cesium (Cs), antimony (Sb), cobalt (Co), thorium (Th), and silver (Ag). Some of the alloy additive elements may be dissolved in the magnesium alloy to form a solid solution. The alloy additive elements that form a solid solution at room temperature may account for 2 wt % or less based on a total weight (100 wt %) of the magnesium alloy, and the alloy additive elements that do not form a solid solution may have crystalline phases.

As used herein, the expression “form a solid solution” means that the alloy additive elements added to magnesium form a solid solution with the magnesium. When the additive elements added in the magnesium alloy are dissolved in magnesium to form a solid solution, the dissolved elements may be homogeneously dissolved in magnesium and may substitute for a magnesium atom. These substituted alloy elements may act as scattering centers that serve as obstacles blocking a path of heat-transferring electrons in the alloy, thereby lowering thermal conductivity.

Accordingly, the magnesium alloy may include one or more alloy additive elements selected from the group consisting of silicon (Si), calcium (Ca), tin (Sn), yttrium (Y), iron (Fe), nickel (Ni), copper (Cu), cerium (Ce), cesium (Cs), antimony (Sb), cobalt (Co), thorium (Th), and silver (Ag), which have low solid solubility, as main additive elements. The magnesium alloy, other than the additive elements, may include magnesium and other unavoidable impurities.

Some of the main alloy additive elements may be dissolved in the magnesium alloy to form a solid solution. The dissolved alloy additive elements that form the solid solution at room temperature, may account for 2 wt % or less, based on a total weight (100 wt %) of the magnesium alloy, and the alloy additive elements that do not form the solid solution may have crystalline phases. In the alloys having the range of solid solubility as mentioned above, with elements having crystalline phases, the crystalline phases may be locally formed and a small amount of these crystalline phase additive elements may act as scattering centers, in contrast to the solid solution with the additive elements being homogeneously dissolved in the magnesium alloy. Therefore, it may be possible to provide a magnesium alloy having high thermal conductivity by using additive elements which form crystalline phases, only a small amount of which act as scattering centers, rather than alloy additive elements having high solid solubility.

Hereinafter, embodiments are described with reference to embodiments in which silicon (Si) and calcium (Ca) are selected from among the alloy additive elements as examples. When silicon (Si) is included in magnesium, it does not form a solid solution at room temperature, but forms a magnesium-silicon crystalline phase (Mg₂Si). The magnesium-silicon crystalline phase may be formed as at least one phase of eutectic phases or primary phases.

Calcium (Ca) may primarily form a crystalline phase at room temperature, like silicon, because it is barely dissolved in magnesium at room temperature to form a solid solution, although a very small amount of calcium may be dissolved in magnesium at room temperature to form a solid solution. In this case, the magnesium-calcium crystalline phase may also form one or more phases of eutectic phases and primary phases.

When one or more alloy additive elements selected from the group consisting of tin (Sn), yttrium (Y), iron (Fe), nickel (Ni), copper (Cu), cerium (Ce), cesium (Cs), antimony (Sb), cobalt (Co), thorium (Th), and silver (Ag) are selected as main alloy additive elements, only crystalline phases may be formed without a solid solution, like Mg—Si, or most of elements form crystalline phases at room temperature with the solid solubility of 2 wt % or less, like Mg—Ca. Therefore, when these alloy additive elements are added to form a magnesium alloy, it magnesium-silicon possible to minimize the deterioration of thermal conductivity by the solid solution and achieve high thermal conductivity.

The high thermally conductive magnesium alloy may include 0.1 wt % to 5.0 wt % of silicon (Si) and 0.1 wt % to 2.0 wt % of calcium (Ca), for example 0.1 wt % to 3.0 wt % of silicon (Si) and 0.1 wt % to 2.0 wt % of calcium (Ca), based on the total weight (100 wt %) of the magnesium alloy. The crystalline phases derived from the addition of silicon and calcium may account for 0.1 wt % to 7.0 wt %, based on the total weight (100 wt %) of the magnesium alloy.

If a content or an amount of silicon becomes too high, the temperature at which a molten metal is produced may rise very high, for example, up to about 800° C., due to the high melting point of silicon, and, therefore, the content of silicon may be in a range of 0.1 wt % to 5.0 wt %. That is, if the content or amount of silicon is too high, the temperature for preparing a molten metal becomes too high, which may cause side effects, such as, for example, decrease in flow and decrease in thermal conductivity.

The content or amount of silicon may be in a range of 0.1 wt % to 3.0 wt % so as to be sufficient to allow a process temperature to be maintained at 730° C. or less. Since the temperature of a molten metal in equipment during casting as well as the process temperature for preparing an alloy also increase when the temperature of the molten metal is too high, restricting or minimizing a temperature of the molten metal up to certain temperature may be necessary. In order to minimize the temperature of a molten metal, its silicon content may need to be near a eutectic point. In this case, the silicon content may be in a range of 0.8 wt % to 1.3 wt % so that the temperature of the molten metal is maintained to be 630° C. or less.

A content or an amount of calcium (Ca) may be in a range of 0.1 wt % to 2.0 wt %. Calcium may be in the magnesium alloy under the form of CaO, thereby preventing oxidation and increasing ignition resistance. In addition, calcium may be in the magnesium alloy as a crystalline phase, for example, of Mg₂Ca, MgCaSi, to improve the strength of the magnesium alloy. Since an excessive amount of calcium above this range may increase or produce hot tear cracking or hot tearing, the amount of calcium may be in a range of 0.1 wt % to 1.0 wt %.

In the high thermally conductive magnesium alloy, a total amount of crystalline phases of the added alloy additive elements may be in a range of 0.1 wt % to 7.0 wt %, based on the total weight (100 wt %) of the magnesium alloy. When the total amount of the added alloy additive elements in crystalline phases exceeds the range mentioned above, the presence of the crystalline phases themselves also may increase thermal conductivity resistance to make it difficult to obtain a high thermally conductivity alloy, and, therefore, the total amount may need to be limited to the range mentioned above.

The crystalline phase of the high thermally conductive magnesium alloy may form at least one phase of eutectic phases and primary phases, and a ratio of the primary phases to the eutectic phases may be 0 to 3.0. When the ratio of the primary phases to the eutectic phases exceeds 3.0, the melting point of the magnesium alloy increases, and the primary phases generated in advance at a high temperature may act as obstacles for the flow of the molten metal, thereby deteriorating flow during casting. Therefore, the ratio of the primary phases to the eutectic phases may be 0 to 3.0.

The high thermally conductive magnesium alloy may further include 0.1 wt % to 6.0 wt % of zinc (Zn), based on the total weight (100 wt %) of the magnesium alloy, thereby increasing strength of the magnesium alloy. However, if the amount or input of zinc increases, hot tear cracking may be greatly affected, and, thus, the magnesium alloy may include 0.1 wt % to 4.0 wt % of zinc.

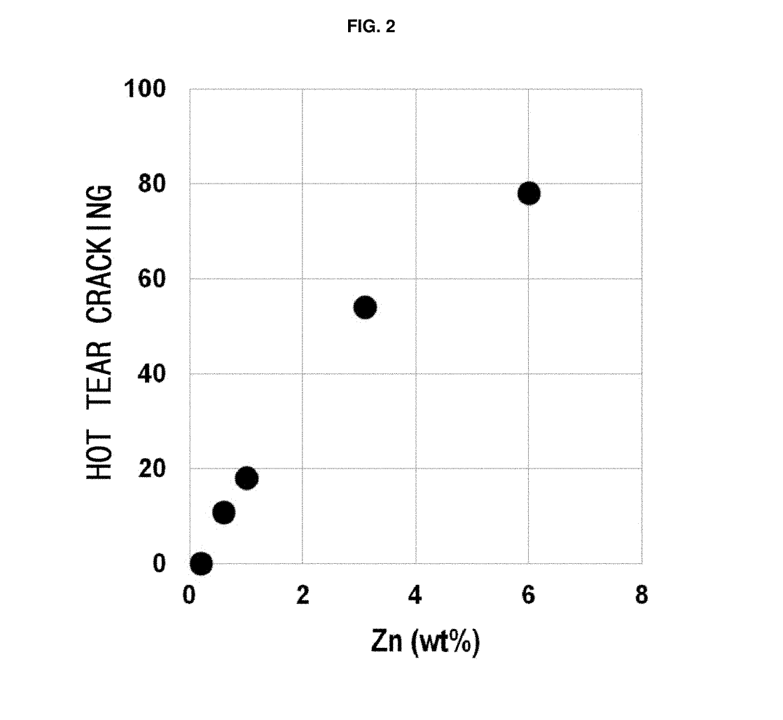

FIG. 2 is a graph showing hot tear cracking depending on the amount or content of zinc (Zn) in wt %. The hot tearing point (y-axis) was calculated by making the hot tearing sample and weighting the cracking position and degree in the range of 0˜240. As shown in FIG. 2, hot tear cracking or hot tearing increases depending on the amount or content of zinc, and, therefore, an amount or content of zinc may need to be as small as possible. When the zinc content is 6 wt %, hot tear cracking reaches about 80, but when the zinc content is 4 wt % or less, hot tear cracking is decreased to about 60. Moreover, when the zinc content is 2 wt % or less, the hot tear cracking, which adversely affects casting, may be lowered to 20 or less. Therefore, for example, zinc may be contained or included in the magnesium alloy in an amount of 0.1 wt % to 2.0 wt %.

The high thermally conductive magnesium alloy may further include 0.1 wt % to 1.0 wt % of aluminum (Al), based on the total weight (100 wt %) of the magnesium alloy, for improving strength and casting. Since aluminum is an element that sharply decreases thermal conductivity, aluminum may not be included beyond the above range.

The magnesium alloy may be formed according to the following process. The following process describes an embodiment wherein silicon and calcium may be added as alloy additive elements, and zinc and aluminum may be further added.

First, an appropriate amount of pure magnesium is completely dissolved in a melting furnace by heating to 650° C. to 700° C. under an oxidation-preventing atmosphere or environment. Oxidation prevention may be performed by a process of surrounding magnesium with a separate anti-oxidation flux, or a process of using oxidation-preventing gases (Ar, CO₂, N₂, SF₆).

Alloy additive elements (Si, Ca) are added to the pure magnesium dissolved in this way and completely dissolved by thorough stirring. An order and temperature of the addition may be adjusted depending on the process and the condition. First, calcium may be added. Then silicon may be added, and the silicon may be dissolved by stirring. Then zinc and aluminum, the remaining elements that may be dissolved easily, may be introduced. However, the present disclosure is not limited thereto, and it may also be possible that silicon is added and sufficiently dissolved by the stirring process, and then the remaining elements are added one after another or at the same time, or all elements are simultaneously added and dissolved by sufficient stirring. Alternatively, a process may be employed, in which all elements are simultaneously added and dissolved at the first step dissolving pure magnesium.

The added alloy additive elements may be used in their pure metal forms or in master alloy forms. For example, in the case of silicon with a very high melting point, addition in its master alloy form may help to make dissolution easier. Aluminum and zinc may be easily dissolved due to their relatively low melting point and high solid solubility in magnesium. When the alloy is sufficiently dissolved, surface impurities of a molten metal may be removed, moisture on the surface may be removed, and then the molten metal may be introduced into a casting mold heated to about 200° C., and cooled to obtain a cast alloy.

The high thermally conductive magnesium alloy may be produced as described above. However, the present disclosure is not limited thereto, and the alloy melting method and the casting method may be replaced with various other methods. The high thermal conductive magnesium alloy may be used as a casting material or a wrought product. It may be manufactured and used as an alloy for general casting, including gravity casting, centrifugal casting, and die casting, and it may be manufactured and used as a wrought product, for example, for extrusion and rolling.

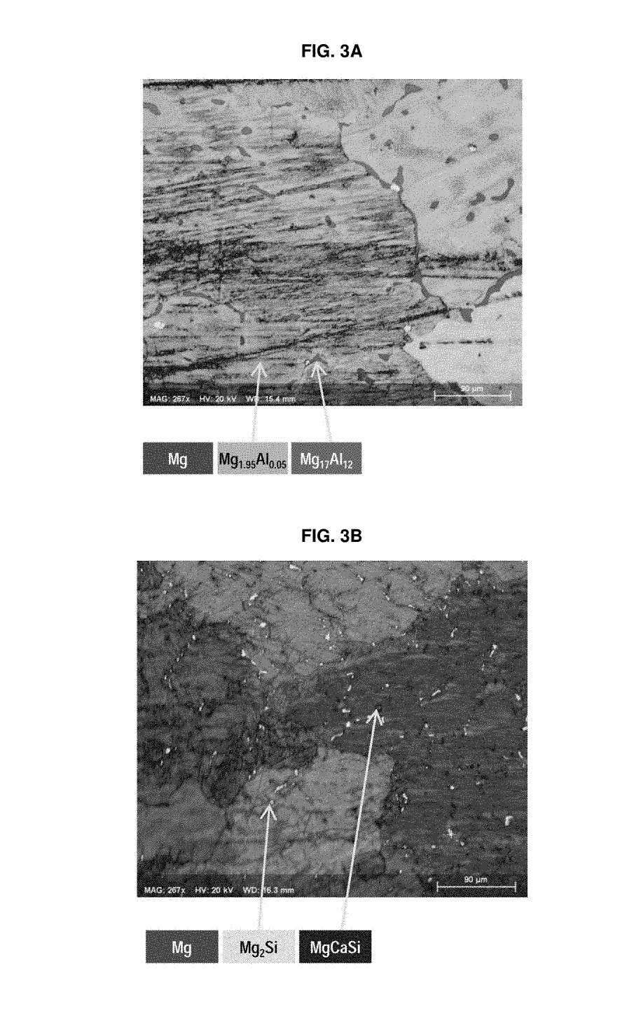

FIG. 3A and FIG. 3B are images of Electron Back Scattered Diffraction (EBSD) phase maps showing crystalline phase patterns to compare microstructures of the high thermally conductive magnesium alloy including 0.8 wt % of silicon and 0.3 wt % of calcium as alloy additive elements with AZ91, a commercial magnesium alloy containing a large amount of aluminum. In the high thermally conductive magnesium alloy, there is no solid solubility of silicon, and even in the case of calcium, there is almost no solid solubility at room temperature, and, thus, a ratio of the crystalline phases may be about 1.1 wt %.

As shown in FIG. 3A, in the case of AZ91, a commercial magnesium alloy, almost no magnesium single phase is observed, and most structures are Mg_{1.95}Al_{0.05}, which is a solid solution phase wherein aluminum is dissolved in magnesium. Mg₁₇Al₁₂ crystalline phase, which is an intermetallic compound of magnesium and aluminum, is formed in grain boundary and grain.

Since the aluminum element dissolved in magnesium is homogeneously dissolved in magnesium to form a solid solution, it may act as a kind of a scattering center when free electrons of magnesium metal move, thereby serving as a factor to reduce thermal conductivity. Therefore, in the commercial magnesium alloy, which contains a large amount of aluminum and most elements of which are dissolved to form a solid solution, its thermal conductivity is decreased.

On the other hand, a microstructure of the high thermally conductive magnesium alloy has characteristics different from those of such a commercial alloy. FIG. 3B illustrates the phase microstructure of the high thermally conductive magnesium alloy. In the magnesium alloy, unlike commercial alloys, pure magnesium single phase is distributed overall, and silicon, a main additive element, forms a crystalline phase, not a solid solution, in magnesium. For example, silicon forms Mg₂Si and MgCaSi phases, and is distributed in grain boundary and grain in the magnesium alloy, with the shape of grains as a crystalline phase different from that of magnesium. Silicon in the high thermally conductive magnesium alloy does not form a solid solution, but forms eutectic phases and primary phases in crystalline phases, specifically, Mg₂Si and MgCaSi phases.

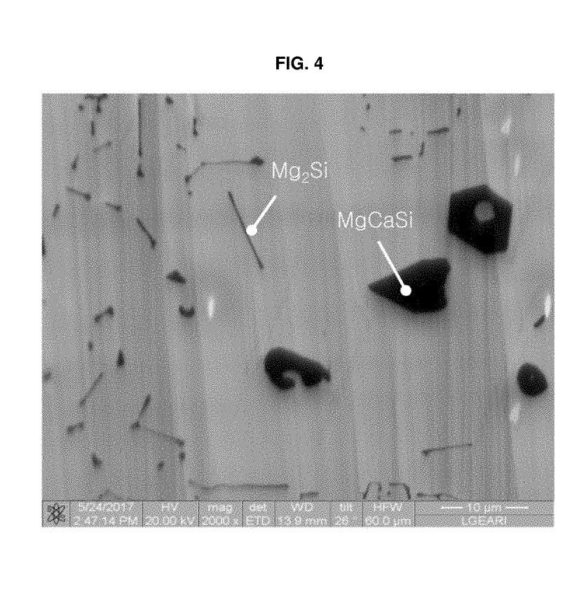

FIG. 4 shows a silicon crystalline phase structure in the magnesium alloy of FIG. 3B magnified by a Scanning Electron Microscope (SEM). The needle-like structures are eutectic phases of Mg₂Si, and the grains in plate or polygon form are primary phases of MgCaSi. Therefore, silicon in the magnesium alloy are present as eutectic phases as well as primary phases.

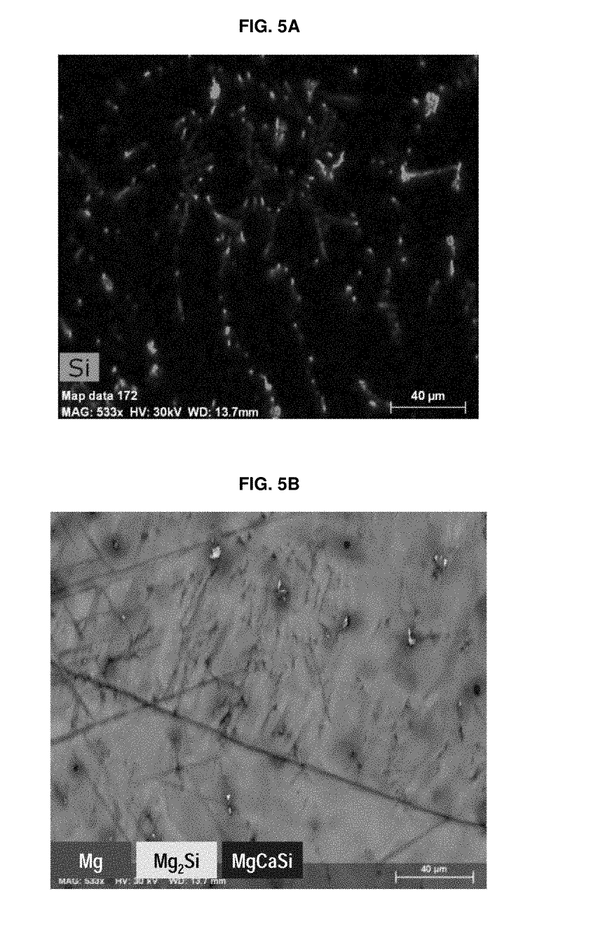

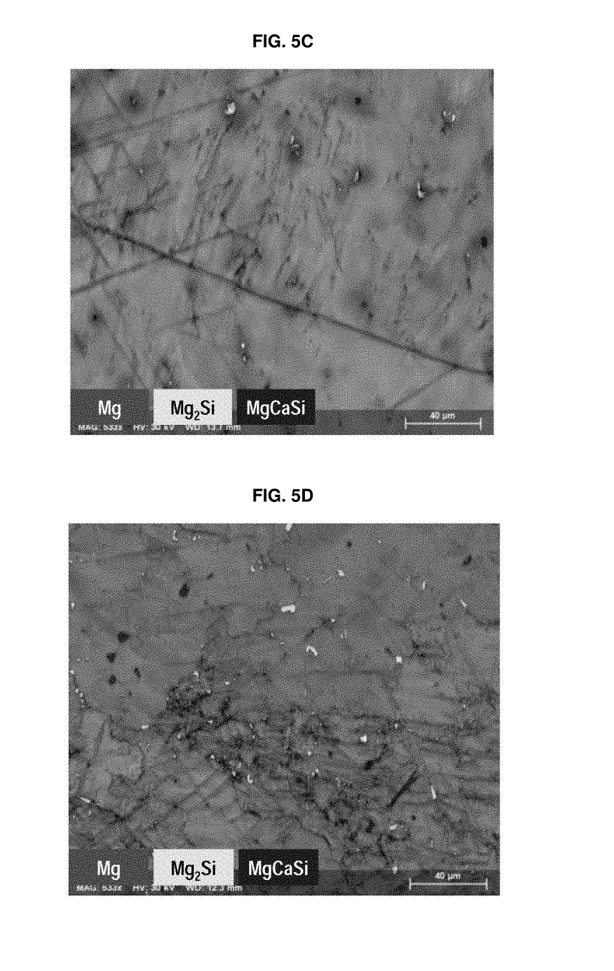

FIG. 5A to FIG. 5D shows the microstructures of the magnesium alloy samples, observed with an electron microscope Energy Dispersive Spectrometer (EDS) and EBSD. FIG. 5A and FIG. 5C are EDS and EBSD images of a hypo-eutectic state in which the silicon content of the state diagram is as small as 0.65%, and FIG. 5B and FIG. 5D are EDS and EBSD images of a hyper-eutectic state in which the silicon content is as much as 1.6%.

Comparing FIG. 5A and FIG. 5C with FIG. 5B and FIG. 5D, many primary phases in the form of grains are formed in the hyper-eutectic sample, unlike the hypo-eutectic sample in which the eutectic phases are predominant. Mg₂Si and MgCaSi are predominantly observed in the primary phases. While the eutectic phases are predominantly formed in the hypo-eutectic sample with low silicon content, the primary phases are formed together with the eutectic phases when the silicone content increases to exceed a eutectic point. As the silicon content increases, resultant primary phases increase, and, since the excessive primary phases decrease thermal conductivity and flow, the ratio of the primary phases to the eutectic phases may be limited to the range of 0 to 3.0.

Densities and thermal conductivities of Examples and Comparative Examples were measured and compared through experimentation. Comparative Example 1, in which the Al component accounts for 2 wt %, as shown in the following Table 1, is a case of more than 1 wt % of additive element, Comparative Example 2, in which the solid solubility is 3 wt %, is a case of more than 2 wt % of additive element, Comparative Example 3, in which the crystalline phases account for 10 wt %, is a case of more than 7 wt % of additive element, Comparative Example 4 is the commercial alloy AZ91, and Comparative Example 5 is the commercial alloy AS21 containing silicon.

Examples 1 to 7 are results of measuring a composition ratio of the additive elements according to the present disclosure at various ratios. In Examples 1 to 7, Si and Ca have almost no solid solubility at room temperature, and in Example 6 having the largest crystalline phase ratio, the crystalline phase ratio is 6.7 wt %, which is less than 7 wt %.

A circular specimen with the diameter of 12.5 mm×2t was fabricated and then its density measured by Archimedes' method. The thermal diffusivity of the same specimen was measured using Laser Flash Analysis (LFA) equipment, and then the thermal conductivity was determined. The composition of each element was measured by Inductively Coupled Plasma (ICP) spectroscopy. In addition, the solid solubility and the fraction of crystalline phases were measured by EDS and EBSD mapping.

TABLE 1

| | | | | | | | | Thermal |
|---|---|---|---|---|---|---|---|---|
| | Mg | Si | Zn | Ca | Al | Sn | Density | Conductivity |
| | (wt %) | (wt %) | (wt %) | (wt %) | (wt %) | (wt %) | (g/cc) | (W/m · K) |
| Comparative | 96.1 | 0.8 | 1 | 0.1 | 2 | | 1.74 | 81 |
| Example 1 | | | | | | | | |
| Comparative | 93.9 | 0.6 | | 0.7 | | 4.8 | 1.82 | 89 |
| Example 2 | | | | | | | | |
| Comparative | 86.6 | 2.5 | 8.7 | 2.2 | | | 1.88 | 92 |
| Example 3 | | | | | | | | |
| Comparative | 89.3 | | 1 | | 9.7 | | 1.81 | 51 |
| Example 4 | | | | | | | | |
| Comparative | 96.8 | 1 | | | 2.2 | | 1.76 | 81 |
| Example 5 | | | | | | | | |
| Example 1 | 99.5 | 0.2 | 0.25 | 0.1 | | | 1.71 | 139 |
| Example 2 | 97.5 | 0.9 | 1 | 0.6 | | | 1.76 | 130 |
| Example 3 | 96.8 | 1.6 | 1 | 0.6 | | | 1.77 | 122 |
| Example 4 | 95 | 2.6 | 1 | 1.3 | | | 1.76 | 115 |
| Example 5 | 94 | 2.1 | 3 | 1.3 | | | 1.79 | 112 |
| Example 6 | 90 | 1.7 | 6 | 2.0 | | | 1.83 | 105 |
| Example 7 | 97.1 | 0.8 | 1 | 0.1 | 1 | | 1.74 | 100 |

As shown in Table 1, the samples according to examples of the present disclosure produce a high thermally conductive magnesium alloy having a thermal conductivity of 100 W/m·K or more over the range of samples. Referring to the Comparative Examples, Comparative Example 1 including 2 wt % of aluminum, in which the composition of the other additive elements is similar to that of the present disclosure, has a thermal conductivity of 81 W/m·K, which is lower as compared with that of Example 7 including 1 wt % of aluminum. Comparative Example 4 including a large amount of aluminum has a thermal conductivity near 50 W/m·K, and Comparative Example 5 has a thermal conductivity near 80 W/m·K. Therefore, aluminum may need to be limited to 1 wt % or less in order to obtain a high thermally conductive magnesium alloy having a thermal conductivity of 100 W/m·K or more.

Comparative Example 2 is an alloy having a solid solubility of 3 wt %, which is more than 2 wt %, and a thermal conductivity was measured as 89 W/m·K, and Comparative Example 3 is an alloy having crystalline phases of 10 wt %, which is more than 7 wt %, and a thermal conductivity thereof was measured as 92 W/m·K. These results show that, in a magnesium alloy having properties that exceed the ranges of the present disclosure, a thermal conductivity of the magnesium alloy is lowered to 100 W/m·K or less. While conventional magnesium alloys for die casting do not exceed 80 W/m·K in thermal conductivity, examples of the present disclosure show a high thermal conductivity of 100 W/m·K or more.

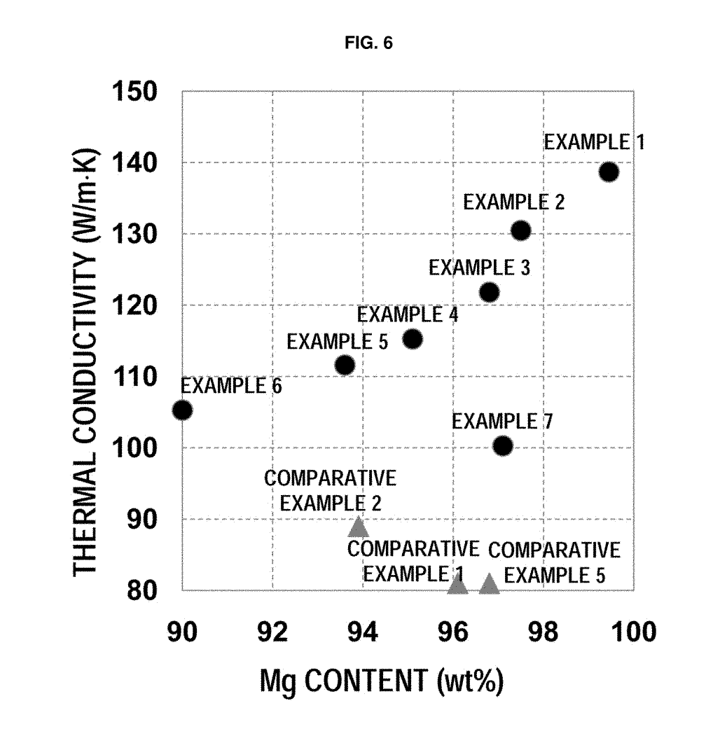

FIG. 6 is a graph of thermal conductivities of examples of the present disclosure and Comparative Examples based on Mg content. For most examples except Example 7, overall thermal conductivities are inversely proportional to content of the additive elements, and for Example 7 including Al, the thermal conductivity is lower than those of the other examples.

Embodiments disclosed herein may provide a magnesium alloy which may be more lightweight and may have excellent or higher thermal conductivity compared to other magnesium alloy materials. Embodiments disclosed herein may provide a heat sink including a lightweight, high thermally conductive magnesium alloy suitable for a material for heat sinks that require lightweight and excellent heat dissipation characteristics. Embodiments disclosed herein may also provide a lightweight, high thermally conductive magnesium alloy with high thermal conductivity that may be used as a casting material castable by a casting method, such as, for example, die casting, and a heat sink including the magnesium alloy.

According to embodiments disclosed herein, a magnesium (Mg) alloy may include one or more alloy additive elements selected from the group consisting of silicon (Si), calcium (Ca), tin (Sn), yttrium (Y), iron (Fe), nickel (Ni), copper (Cu), cerium (Ce), cesium (Cs), antimony (Sb), cobalt (Co), thorium (Th), and silver (Ag). Some of the alloy additive elements may be dissolved in the magnesium alloy to form a solid solution, the alloy additive elements, forming the solid solution at room temperature, may account for 2 wt % or less, with respect to the total weight (100 wt %) of the magnesium alloy, and the alloy additive elements, not forming the solid solution, may be in crystalline phase. The crystalline phases may include at least one of eutectic phases and primary phases, and a ratio of the primary phases to the eutectic phases is 0 to 3.0.

The alloy additive elements may be silicon (Si) and calcium (Ca), and the magnesium alloy may include 0.1 wt % to 5.0 wt % of silicon (Si) and 0.1 wt % to 2.0 wt % of calcium (Ca), based on the total weight (100 wt %) of the magnesium alloy, and the crystalline phases may account for 0.1 wt % to 7.0 wt %, based on the total weight (100 wt %) of the magnesium alloy. The crystalline phases may include at least one of Mg₂Si and MgCaSi.

The magnesium alloy may further include 0.1 wt % to 6.0 wt % of zinc (Zn) and 0.1 wt % to 1.0 wt % of aluminum (Al), based on the total weight (100 wt %) of the magnesium alloy. According to embodiments disclosed herein, a heat sink including the magnesium alloy having the above characteristics may be provided.

Although the exemplary embodiments of the present disclosure have been described for illustrative purposes, those skilled in the art will appreciate that various modifications, additions and substitutions are possible without departing from the scope and spirit of the present disclosure. Accordingly, it may be understood that such modifications, additions and substitutions also fall within the scope of the present disclosure.

When an element or layer is referred to as being “on” another element or layer, the element or layer may be directly on another element or layer or intervening elements or layers. In contrast, when an element is referred to as being “directly on” another element or layer, there may be no intervening elements or layers present. As used herein, the term “and/or” includes any and all combinations of one or more of the associated listed items.

Although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section could be termed a second element, component, region, layer or section without departing from the teachings of the present disclosure.

Spatially relative terms, such as “lower”, “upper” and the like, may be used herein for ease of description to describe the relationship of one element or feature to another element(s) or feature(s) as illustrated in the figures. Spatially relative terms are intended to encompass different orientations of the device in use or operation, in addition to the orientation depicted in the figures. For example, if the device in the figures is turned over, elements described as “lower” relative to other elements or features would then be oriented “upper” relative the other elements or features. Thus, the exemplary term “lower” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. The terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the disclosure are described herein with reference to cross-section illustrations that are schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this disclosure belongs. Terms, such as those defined in commonly used dictionaries, should be interpreted as having a meaning that is consistent with their meaning in the context of the relevant art and will not be interpreted in an idealized or overly formal sense unless expressly so defined herein.

Any reference in this specification to “one embodiment,” “an embodiment,” “example embodiment,” etc., means that a particular feature, structure, or characteristic described in connection with the embodiment is included in at least one embodiment. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A magnesium (Mg) alloy, comprising:
magnesium (Mg); and
one or more alloy additive elements selected from the group consisting of silicon (Si), calcium (Ca), tin (Sn), yttrium (Y), iron (Fe), nickel (Ni), copper (Cu), cerium (Ce), cesium (Cs), antimony (Sb), cobalt (Co), thorium (Th), and silver (Ag),
wherein some of the one or more alloy additive elements are dissolved in the magnesium alloy to form a solid solution, and
wherein the some of the one or more alloy additive elements forming the solid solution at a room temperature account for 2 wt % or less with respect to a total weight of the magnesium alloy of 100 wt %, and remaining alloy additive elements are in crystalline phases.

2. The magnesium alloy according to claim 1, wherein the crystalline phases are in at least one of eutectic phases or primary phases.

3. The magnesium alloy according to claim 2, wherein a ratio of the primary phases to the eutectic phases is 0 to 3.0.

4. The magnesium alloy according to claim 1, wherein the alloy additive elements are silicon (Si) and calcium (Ca), and the magnesium alloy includes 0.1 wt % to 5.0 wt % of silicon (Si) and 0.1 wt % to 2.0 wt % of calcium (Ca), based on the total weight of the magnesium alloy of 100 wt %.

5. The magnesium alloy according to claim 1, wherein the alloy additive elements are silicon (Si) and calcium (Ca), and the magnesium alloy includes 0.1 wt % to 3.0 wt % of silicon (Si) and 0.1 wt % to 2.0 wt % of calcium (Ca), based on the total weight of the magnesium alloy of 100 wt %.

6. The magnesium alloy according to claim 1, wherein the alloy additive elements are silicon (Si) and calcium (Ca), and the magnesium alloy includes 0.8 wt % to 1.3 wt % of silicon (Si) and 0.1 wt % to 2.0 wt % of calcium (Ca), based on the total weight of the magnesium alloy of 100 wt %.

7. The magnesium alloy according to claim 4, wherein the crystalline phases account for 0.1 wt % to 7.0 wt %, based on the total weight of the magnesium alloy of 100 wt %.

8. The magnesium alloy according to claim 4, wherein the magnesium alloy further includes 0.1 wt % to 6.0 wt % of zinc (Zn), based on the total weight of the magnesium alloy of 100 wt %.

9. The magnesium alloy according to claim 4, wherein the magnesium alloy further includes 0.1 wt % to 4.0 wt % of zinc (Zn), based on the total weight of the magnesium alloy of 100 wt %.

10. The magnesium alloy according to claim 4, wherein the magnesium alloy further includes 0.1 wt % to 2.0 wt % of zinc (Zn), based on the total weight of the magnesium alloy of 100 wt %.

11. The magnesium alloy according to claim 8, wherein the magnesium alloy further includes 0.1 wt % to 1.0 wt % of aluminum (Al), based on the total weight of the magnesium alloy of 100 wt %.

12. The magnesium alloy according to claim 4, wherein the crystalline phases include at least one selected from the group consisting of Mg₂Si, Mg₂Ca, and MgCaSi.

13. A heat sink made from the magnesium alloy according to claim 1.
